(19) United States
(12) Patent Application Publication
(10) Pub. No.: US 2005/0242063 A1
(43) Pub. Date: Nov. 3, 2005

(54) Method and device for the chemical mechanical polishing of workpieces

(76) Inventors: Ulrich Ising, Budelsdorf (DE); Marc Reichmann, Eckernforde (DE); Thomas Keller, Osterronfeld (DE)

Correspondence Address: VIDAS, ARRETT & STEINKRAUS, P.A., 6109 BLUE CIRCLE DRIVE, SUITE 2000, MINNETONKA, MN, 55343-9185, US

(21) Appl. No.: 10/511,651

(22) PCT Filed: Mar. 11, 2003
(86) PCT No.: PCT/EP03/02469

§ 371 Date: May 23, 2005

Related U.S. Application Data
(63) Continuation-in-part of application No. 10/125,862, filed on Apr. 19, 2002, now Pat. No. 6,780,083.

(51) Int. Cl. B44C 1/22; H01L 21/306; C23F 1/00

(52) U.S. Cl. 216/88; 438/692; 156/345.12

(57) ABSTRACT

Method for transporting, chemical-mechanical polishing and drying of workpieces, in particular silicon wafers in a sealed clean room with the following steps: the workpieces are removed by at least one transfer device from a loading and unloading station and transferred onto an intermediate station the workpieces are received by at least one polishing head of a polishing device of the intermediate station, transported to a polishing plate of the polishing device and held under rotation of the polishing head against the rotating polishing plate after polishing, the workpieces are transported back by the polishing head to the intermediate station, released from the polishing head and cleaned and/or chemically treated in the intermediate station the cleaned and/or chemically treated workpieces are transported from the intermediate station optionally to a second polishing device or to a washing or drying device and washed and dried therein the washed and dried workpieces are transported back by the transfer device to the loading and unloading station the polishing head is cleaned before each workpiece is received.

### CROSS-REFERENCE TO RELATED APPLICATIONS

This application is a Continuation In Part of U.S. application Ser. No. 10/125,862, filed Apr. 19, 2002, now issued as U.S. Pat. No. 6,780,083B2 the entire contents of which are hereby incorporated by reference.

### STATEMENT REGARDING FEDERALLY SPONSORED RESEARCH

Not applicable.

### BACKGROUND OF THE INVENTION

After each coating of a semiconductor wafer, for example with an oxide layer, a tungsten layer or other metal layers, a processing has to take place in order to produce the desired planar surfaces. Otherwise, problems may occur, for example with lithographic processes, in the form of focus failures by the small focal depth of the UV-stepper or in the form of damage to the conductor paths. A method in the semiconductor industry for planarisation uses the so-called CMP process. This refers to a chemical-mechanical treatment by means of a fluid (slurry), the chemically reactive part of the slurry having the objective of converting the material into a polishable condition. The slurry contains an abrasive in the form of colloidal abrasive small particles.

From DE 197 19 503 A1 a device for the chemical-mechanical polishing of surfaces has become known. It contains two polishing stations with vertically adjustable vacuum chucks or polishing heads for each semiconductor wafer. The polishing stations have polishing plates which can be rotated about a vertical axis. The vacuum chucks are guided along independently of one another by two parallel guides extending approximately horizontally. By this, two wafers can be processed simultaneously by a polishing plate. At least one transfer and receiving device for the wafers is provided at one end of the guides. Furthermore, arranged on opposing sides of the guides loading and unloading devices for the semiconductor wafers are provided, to which the vacuum chucks can be aligned. The transfer and receiving device is normally formed by a robot.

During transportation and processing the wafers are held by the vacuum chuck or a so-called carrier. Its object is to transfer a homogenous pressure field or different pressure profiles onto the rear face of the workpiece. The so-called sharp face, ie the face which is provided with circuits, faces the polishing plate. Usually the carrier is held and moved by an adjusting device which rotates the carrier on the one hand about a vertical axis and on the other hand moves it linearly in the vertical and horizontal direction.

The throughput through a CMP device is mainly dependent on the number of polishing stations. On the other hand, the processing times for the planarisation are very short (typically 90 seconds). Due to the short processing times, bottlenecks may occur when transferring workpieces between the individual sections and limit the throughput.

A further important point regarding chemical-mechanical polishing (CMP) is keeping the workpieces clean. The entire polishing and cleaning process takes place in a clean room and means have to be provided which prevent slurry remainders and slurry particles present after the polishing process from remaining on the surface of the workpiece. Drying such remainders would damage the circuit on the workpiece. From U.S. Pat. No. 5,885,138, for example, the so-called Dry-In-Dry-Out method has become known, where by corresponding transfer processes in the treatment room it is ensured that, for example a transfer device which removes the workpieces from a loading and unloading station, does not come into contact with wet or uncleaned workpieces. With this transfer device, for example a robot, the final cleaned and dried workpieces are again transported back into the loading and unloading station.

The object of the invention is to provide a method and a device for the chemical-mechanical polishing of workpieces, such that at high production speeds a high level of cleanliness of the workpieces is maintained.

### BRIEF SUMMARY OF THE INVENTION

In the method according to the invention the workpieces are first transferred by a transfer device into an intermediate station. Once there they are conveyed to the polishing device. This takes place by means of a polishing head or carrier which is provided with means to receive a workpiece carefully, for example a wafer. The workpiece is transported with the polishing head to the polishing plate of the polishing device and by the rotation of the polishing head held against the rotating polishing plate. After the polishing the workpieces are transported back by the polishing head to the intermediate station, deposited there and cleaned therein. Additionally or alternatively a chemical treatment, for example etching or the like, can also take place in the intermediate station. The cleaned workpieces are then transported from the intermediate station either to a further polishing device or to a washing and drying device in which they are washed and dried. Subsequently they are transported back by the transfer device to the loading and unloading station. The polishing head is cleaned prior to receiving each workpiece.

The wafers can be cleaned on both sides in the intermediate station which naturally cannot take place when they are suspended on the polishing head.

Etching or chemical reactions which are produced by remainders on the workpiece are prevented in the intermediate station. This is particularly advantageous when the workpieces are treated in a two-step or multiple-step CMP process, ie transported from the intermediate station into a further polishing device. By corresponding rinsing and cleaning devices in the intermediate station, so-called cross-contamination can be prevented, ie the mixing of different materials and chemical components between the polishing devices. Furthermore, a chemical pretreatment of the workpieces can take place in the intermediate station in order to prepare them for the polishing stages.

A further advantage of the invention is that after each workpiece is deposited the polishing head is cleaned in a special cleaning station. This cleaning station is preferably arranged at a height where it does not interfere with the cooperation of the polishing head, intermediate station and polishing device. The polishing head can be cleaned alone in the processing and cleaning station, but can also be brought into the cleaning station together with the workpiece so that both are subjected to cleaning.

The gripping means of the transfer device which can consist of a first and a second transfer device to carry out the Dry-In-Dry-Out method, can also be cleaned by means of corresponding cleaning means before each new workpiece is picked up. To keep the contamination particularly low, the gripping means pick up the workpieces only at the edge. As a result, the surface of the workpiece is treated with care.

It is advantageous for carrying out the disclosed method if it can be identified that layer transitions are present. To this end the friction behaviour is measured between the polishing cloth and the layer to be polished, for example via the power consumption of the drive means for the polishing plate. This criterion is generally inadequate for determining the layer transition, in particular when a plurality of workpieces are processed simultaneously on the polishing plate. Therefore the temperature variations of the temperature on the surface of the polishing plate on the one hand and the difference in temperature of the cooling means for the polishing plate on the other hand are evaluated. From the indicated temperature variations it can be determined by means of a suitable algorithm when a layer transition is present.

In an embodiment of the invention the intermediate station comprises a carrier rotatably mounted about a vertical axis which can be rotated by a rotary drive means. The rotatable carrier comprises on its upper face at least two horizontal loading surfaces exposed upwardly. In the device according to the invention, moreover, at least two polishing stations are associated with the circumference of the rotating carrier. Two polishing stations are preferably located on diametrically opposing sides of the carrier. A third polishing station can also be provided which is arranged offset to the other two polishing stations on the circumference of the carrier about an angle of approximately 90°, the transfer device able to be diametrically opposed to the last-mentioned polishing station. The transfer device carries out the loading of the loading surfaces with workpieces and the removal of processed workpieces from the loading surfaces.

The CMP processes can be provided by two or more processing steps in which the workpiece is planarised in different polishing stations. By using different chemicals and polishing cloths in different polishing stations, different materials, such as for example tungsten, copper or titanium nitrite can be processed under optimised conditions. It is important to minimise the transportation times of the workpieces between the polishing stations as the chemical components of the first step can very rapidly lead to further etching of the workpiece. In the device according to the invention a fast transportation from one polishing station to another can take place. By a rapid exchange of the workpieces between the polishing stations, the throughput is increased as the secondary processing times are reduced. By the disclosed embodiment of the device according to the invention, as mentioned above, a plurality of polishing stations can be interconnected so that a more rapid exchange between the stations is possible. With a one-step method the throughput time can also be reduced as the workpieces can be treated during their transportation onto the loading surface, for example a chemical pretreatment can take place and/or rinsing or cleaning after the polishing step.

In the present CMP process technology it is usual to convey the workpiece after the first polishing step to an intermediate cleaning process, in order to minimise or eliminate the aforementioned disadvantageous effects. In the already disclosed publication DE 197 19 503 A1 or U.S. Pat. No. 6,050,885 it is known to provide a stationary cleaning device. According to the invention a cleaning device can also be associated with the carrier so that during the transportation of the workpiece on the carrier cleaning can take place. As a suitable cleaning device is effective during the transportation of the workpieces, undesired etchings on the workpiece can be avoided. Additionally, so-called cross-contamination between the polishing stations is eliminated in a two-step process.

The positioning of the workpieces on the loading surfaces by means of the transfer device is not normally such that the workpieces are correctly centred, so that they can be received in a centred manner by the carrier or polishing head. Therefore the loading surfaces in the device according to the invention are associated with centring means which cooperate with the circumference of a workpiece on the loading surface and align the workpiece with a predetermined vertical axis. The vertical axis of the carrier can be aligned with this axis so that the carrier when lowered over the workpiece on the loading surface can receive the workpiece in a centred manner.

The carrier for the transportation of the workpieces and for cooperating with the polishing plates in the polishing stations can be constructed in the usual manner. Preferably it holds the workpieces by means of a vacuum. Releasing the workpieces from the carrier can be carried out by generating an air pressure pulse after switching off the vacuum. The displacement of the carrier along horizontal and vertical axes is also already known and can be carried out in the manner disclosed by U.S. Pat. No. 6,050,885.

From the aforementioned publication it is known to provide a linear guide for the carriers, two carriers each with a received workpiece being used for each polishing plate. The carriers can be moved on the guide independently from one another. In this case it is advantageous if the carrier comprises four loading surfaces, each two loading surfaces having an axis which is in a plane extending parallel to the guide, when the carrier has a corresponding rotary position. In this manner one loading surface can be provided per carrier, whereby the throughput of the workpieces upon polishing can be considerably increased, in particular with a two- or multi-step planarisation process. The positioning of the four loading surfaces preferably takes place in steps of 90° or a multitude of 90°.

A cleaning device is associated with the carrier. For this it can be provided that the carrier comprises a central elevation in which at least one nozzle which is connected to a fluid source is arranged per loading surface. The nozzle can spray cleaning fluid on the processed surface of the workpiece. It can also serve to wet the surface of the workpiece with a suitable liquid. In such an elevation a number of detectors can also be arranged which determine whether a workpiece is arranged on the loading surface.

It is necessary to centre the workpieces on the loading surfaces so that they can be received by the carrier in a centred manner. There are different known possibilities for this. According to an embodiment of the invention, one possibility consists in that centring cams are provided which are spaced apart on a circle and which have support surfaces to receive the edge region of a workpiece. The centring cams further comprise radially adjustable stop surfaces which may engage the circumference of the workpiece in order to align the workpiece with respect to a predetermined vertical axis. To this end the stop surfaces are synchronously actuated.

The loading surfaces can moreover have a concave shape so that the space between a received workpiece and the loading surface can serve as a cleaning chamber. It is possible to drain fluid from this cleaning chamber by one or more bores in the loading surface. A nozzle can also be arranged in the loading surface for the supply of cleaning fluid to the disclosed chamber between the workpiece and the loading surface. By means of such measures the contact surface of the carriers can also be cleaned when it is lowered onto the loading surface.

Thus a multifunction device is created in which by a rotary movement the individual polishing stations and the transfer device can be interconnected in order to keep the transportation times as short as possible. By means of the multifunction device the throughput can be increased, in particular in a so-called two-step or multi-step process, in which different materials, such as for example tungsten, copper or titanium nitrite are processed with different chemicals and polishing cloths in different polishing stations. By the integration of suitable rinsing and cleaning devices, it is possible to prevent etching and chemical reactions which can be produced by remainders on the workpieces. Furthermore, in the disclosed multifunction device so-called cross-contamination is prevented, ie contamination of different materials and chemical components between the polishing stations. Furthermore, the rinsing and cleaning devices can be used for the chemical pretreatment of the workpieces, in order to prepare them for the second or third polishing step. Since the cleaning, the pretreatment and the like takes place when moved for transportation, the throughput speed is not affected.

### BRIEF DESCRIPTION OF THE SEVERAL VIEWS OF THE DRAWINGS

The invention is to be described in more detail hereinafter with reference to the drawings, in which:

FIG. 1 shows a top view of a device for transporting, polishing and washing and drying of wafers,

FIG. 2 shows a side view of the device according to FIG. 1 in the direction of arrow 2 of FIG. 1,

FIG. 3 shows a part of the side view of the device according to FIG. 1 in the direction of arrow 3 of FIG. 1,

FIG. 4 shows a section through a polishing plate and through polishing heads of the polishing device according to FIG. 1,

FIG. 5 shows a section through a polishing head of the polishing device according to FIG. 4,

FIG. 6 shows diagrammatically the processing of a semiconductor wafer with a polishing plate,

FIG. 7 shows the top view of a very diagrammatically shown device according to the invention,

FIG. 8 shows a section through the carrier of the loading and unloading station according to FIG. 2,

FIG. 9 shows the top view of the loading and unloading station according to FIG. 2,

FIGS. 10a-10o show diagrammatically the sequence of a two-step polishing process according to the method according to the invention,

FIG. 11 shows a top view of a cleaning and processing device of the device according to FIG. 1,

FIG. 12 shows a section through the view according to FIG. 11 in the direction of the line 12-12,

FIG. 13 shows a side view of a gripper of a transfer device of the device according to FIG. 1,

FIG. 14 shows the side view of the gripper according to FIG. 13,

FIG. 15 shows a block diagram for obtaining a shutoff signal for the polishing device.

### DETAILED DESCRIPTION OF THE INVENTION

While this invention may be embodied in many different forms, there are described in detail herein a specific preferred embodiment of the invention. This description is an exemplification of the principles of the invention and is not intended to limit the invention to the particular embodiment illustrated

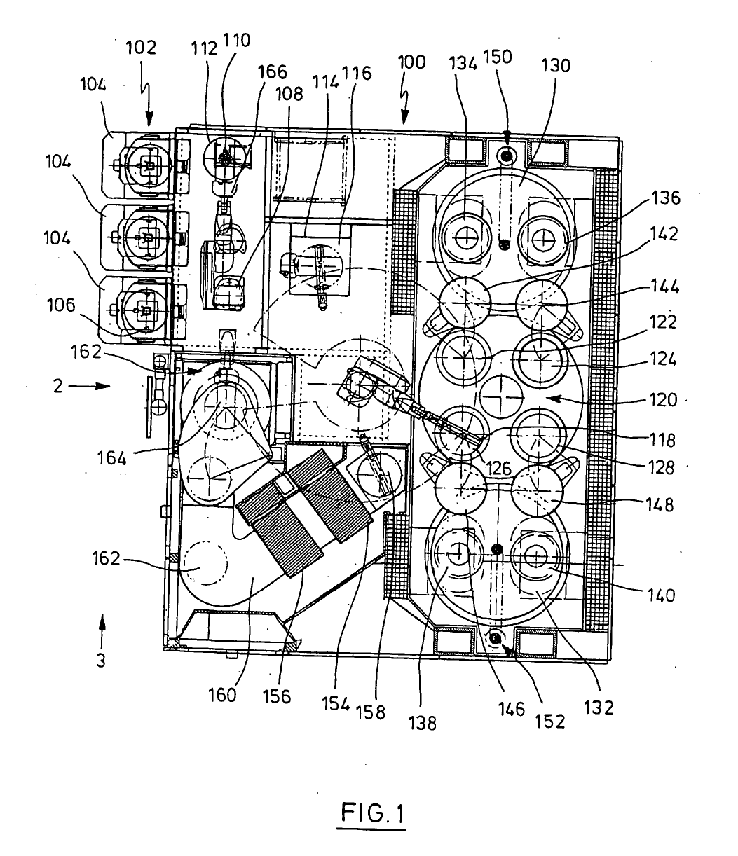

In FIGS. 1 to 3 the outline of a clean room 100 is indicated in which numerous individual units and devices of the device according to the invention are accommodated. They are to be firstly diagrammatically indicated and disclosed with reference to FIGS. 1 to 3. A loading and unloading station is generally designated by 102 which comprises three platforms 104 for cassettes 106 loaded with wafers. The platforms 104 contain a plurality of sensors, which for example detect the exact position of the cassette 106 on the platform or the type of cassette. Furthermore, a cassette identification device is provided which reads corresponding data carriers of the cassettes. This is not to be described in detail. Moreover, a so-called mapping device is also provided which registers the accurate arrangement of wafers in the storage racks of the cassettes and sends a signal to a control device not shown in detail.

A first robot 108 serves to remove the wafers from the cassettes 106, the robot firstly depositing each wafer onto a cassette identification device 110 or holding it therein.

The robot 108 is designed to handle dry wafers. It removes the wafers from the storage racks of the cassettes and transfers them to the identification device 110 (a wafer 112 is shown in the identification device 110). The robot 108 then conveys the wafer 112 to a transfer point 114 at which a thickness gauge 116 is also arranged.

A further robot 118 is arranged approximately centrally in the clean room 100 by means of which the wafer is conveyed from the transfer point 114 to an intermediate station 120. The intermediate station 120 comprises four support surfaces 122 to 128 which are arranged on a rotatable carrier. This will be described below in more detail. On the opposing sides of the carrier a polishing plate 130 and 132 is respectively rotatably driven. Two polishing heads 134, 136 and 138, 140 are assigned to each polishing plate 130. The structure of the polishing plate and the polishing heads, in addition to their movement will be described in more detail below. It has already been mentioned that the polishing heads can be moved linearly between the shown positions in FIG. 1 and a position over a support surface 122 to 128. Furthermore, the polishing heads 134 to 140 can be vertically adjustably arranged. The polishing heads serve to transport the wafers and to hold them against the polishing plates 130, 132, so that they can be treated there in the CMP process. The polishing process will also be described in more detail below.

Between the polishing plate 130 and the intermediate station 120 two processing and cleaning stations 142, 144 are arranged. Similar cleaning stations 146, 148 are arranged between the intermediate station 120 and the polishing plate 132. The processing and cleaning stations can be pivoted between a position, as is marked in FIG. 1 and a position in which it is aligned with a support surface. The stations 142 to 148 are arranged at a distance over the support surfaces 122 to 128, but can be traversed by the polishing heads 134 to 140.

After polishing, the wafers are transported by robots 118 to the thickness gauge 116.

Each polishing plate 130, 132 is associated with a dressing device 150 and 152. This will also be further described below. It can be seen from FIG. 1 that the entire polishing device including the intermediate station 120 and the dressing devices 150, 152 is arranged in a specific section within the clean room 100.

In a further section of the device according to FIG. 1 a washing and drying device is arranged. It contains a main cleaning station 154 and a final cleaning station 156 to where the wafers come from an input area 158. They are put into the input area by robots 118 and from there conveyed via a V-shaped water transfer 160 and through cleaning measures. The cleaning stations will not be described in detail. The cleaned wafers reach a stop point 162 before they enter a centrifugal rinser and drier 162 by means of a robot indicated by 164. The cleaned wafer is then conveyed from the centrifugal rinser and drier 162 by means of the robot 108 to the loading and unloading station 102 and from there transported back with the first robot 108 into a cassette which is already held. It can already be seen that the robot 108 only picks up and transports dry wafers whilst the robot 118 only picks up and transports wet wafers.

It is also noteworthy in FIG. 3 that the gripper 166 can be seen which picks up a wafer 112 and which is to be described in more detail below.

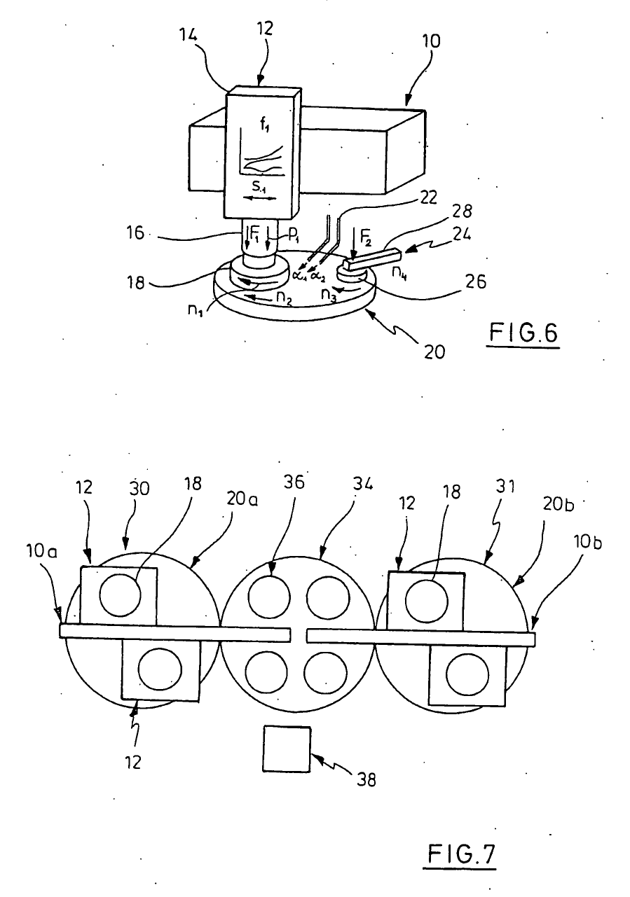

With reference to FIGS. 6 to 10 the polishing operation is now described in more detail with regard to the intermediate station 120.

FIG. 6 shows diagrammatically the known structure of a polishing station, for example for semiconductor wafers. A polishing unit 12 is supported for linear movement on a horizontal linear guide 10 and can be moved along the guide by a not shown drive means. This is indicated by the double arrow S1. The upper portion 14 which is guided on the guide 10 supports a spindle 16 which can be rotatably driven by a not shown motor. The spindle is moreover vertically adjustable. A so-called carrier 18 is mounted at the lower end of the spindle for holding a not shown semiconductor wafer. The carrier 18 can be rotatably driven by means of the spindle 16, ie with the rotational speed n1. A rotatably driven polishing disc 20 is located below the carrier 18 (also referred to above as the polishing head) as is usually used for the planarisation of wafers. The polishing disc 20 is driven with the rotational speed n2. On the not shown polishing cloth of the polishing disc 20 a slurry is supplied by a device 22 with the amounts α1 and α2. By means of a not shown adjusting mechanism for the vertical adjustability of the spindle 16 a pressure b1 can be exerted in order to press the wafer against the polishing disc 10 with a predetermined pressure.

A not shown dressing mechanism 24 contains a dressing disc 26 which is rotatably mounted on an arm 28 and is driven with a rotational speed n3. The force by which the dressing disc 26 is pressed is F₂.

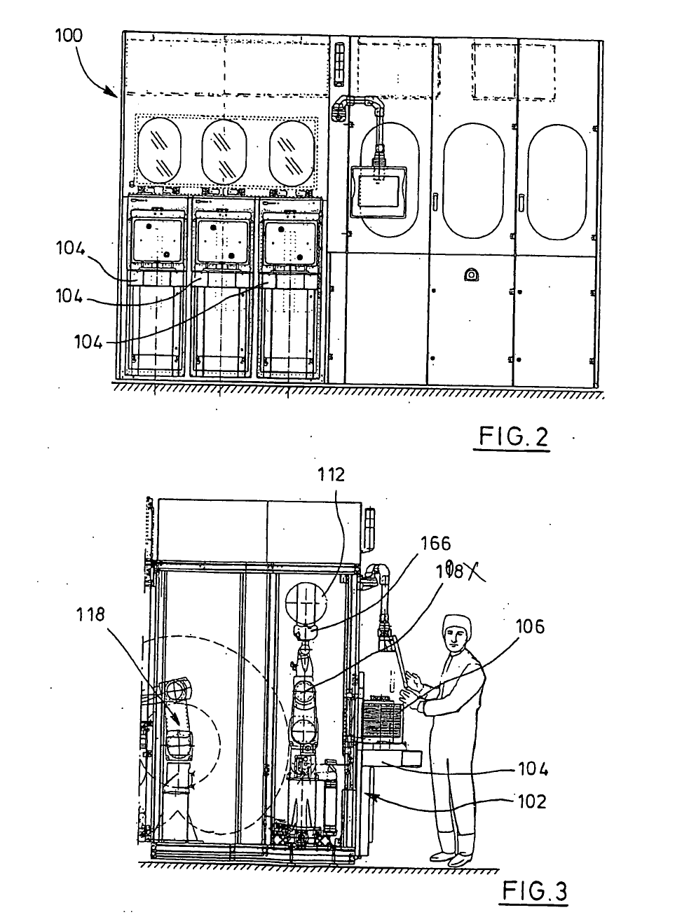

In the diagrammatic illustration according to FIG. 7 two polishing stations 30, 31 are provided which resemble those of FIG. 6, each polishing station being associated with two polishing units 12 which are guided on linear guides 10a and 10b. The guides 10a and 10b lie on an axis. The structure of the polishing units 12 according to FIG. 2 corresponds to that according to FIG. 6. The arrangement of the polishing units on the guides 10a, 10b corresponds to that shown and described in U.S. Pat. No. 6,050,885.

A circular carrier 34 is arranged between the polishing stations 30, 31 for the intermediate station 120 according to FIG. 1 and which can be rotated about a central vertical axis by a rotary drive means not shown in FIG. 7. The guides 10a, 10b are extended to the right and left and extend over the carrier 34 approximately to the centre thereof. The centres of the polishing plates 20a, 20b and the carrier 34 are on an axis which is parallel to the guides 10a, 10b.

Two loading and unloading points 36 are respectively arranged on on the carrier on opposing sides of this axis and which will be subsequently described in more detail and correspond to the loading surfaces 122 to 128. Their centres are positioned on a circle concentric to the rotary axis of the carrier 34. Each of the four loading and unloading points 36 is in a position to receive a wafer in a centred manner. The loading and unloading of these points 36 takes place by means of a diagrammatically illustrated robot 38, thus for example the robot 118 according to FIG. 1.

In the rotary position shown in FIG. 7 the polishing units 12 can be respectively aligned with two loading and unloading points 36, in order to receive or deposit a wafer. It is understood that a third polishing station can be provided. It is located on the circumference of the carrier 34 on the opposite side of the robot 38.

The structure of the loading and unloading points is more clearly seen in FIGS. 8 and 9 which are to be described in more detail hereinafter.

The carrier 34 is rotatably mounted about a vertical axis in an opening of a stationary frame 40. It comprises a plurality of parts. A circular plate 42 is connected fixedly in rotation to a wheel 44 which can be rotated about a vertical axis by a gear 46 and a driving motor 48. The plate 42 also rotates with the rotation of the wheel 44. Trunnion-shaped holders 50 are arranged on the plate 42. The holders stand vertically upwards and support cap-shaped elements 52. The support is resilient in the axial direction by means of a spring 51. The upper face of the elements 52 forms a loading surface 54 for wafers 56 which can be placed on the loading surface. Four centring cams 58 are arranged at the circumference of the loading surface 54 in a circumferentially spaced manner. They comprise a support surface for the wafers 56, not shown in more detail. As a result the wafers 58 are supported only on four points at the edge (in FIG. 8 only two centring cams 58 can respectively be seen). In FIG. 9 the four centring cams 58 can be seen. The radially movable centring cams have a stop surface which can be radially moved by an adjusting mechanism. The adjusting mechanism comprises a pneumatic rotary drive 61 which acts on four rods 65 via a gear 63, in order to move the cams 58. These are formed as levers which are pivoted by the rods 65. The stop surfaces are also not shown. By means of the stop surfaces or the centring cams 58 a received wafer disc can be centred relative to a predetermined axis, for example the centre axis of the element 52.

A throughbore 62 is shown in the top wall of the element 52 which is provided with a connection fitting 64 for a fluid. Fluid can be conveyed to the lower face of the received wafer via the connection fitting. Bores can also be provided in order to remove liquid from the loading surface.

Spaced from the plate 42 a plate 66 is fixedly attached to the plate 42 which in the region of the elements 52 comprises openings 68. In the centre the plate 64 comprises an elevation 70 with an inner hollow space which is aligned with an axial through-passage 72 from wheel 44 to plate 42. In the slightly oblique wall in the upper region of the elevation 70 a plurality of nozzles is arranged, of which one is shown at 74. A nozzle 74 is respectively associated with a loading and unloading station 36, ie to its loading surface 54. A conduit 76 guided to the nozzle 74 is connected to a fluid source in order to spray a fluid onto the upper face of the received wafer 56. A radiation source 78 is also provided for each loading and unloading station 36 which is directed toward the loading surface 54 and cooperates with a receiver 79 which indicates whether a wafer 56 is received or not.

The carrier 34 is encircled by a sealing ring 80 of the frame 40, a labyrinth seal 82 being provided between the ring 80 and the plate 66. A dripping tub (not shown) for the entire system is located below the ring 80. Each cap-shaped element 52 is also encircled by a dripping tub 82, in order to receive liquid or slurry and to drain it into the dripping tub for the entire system in a manner not shown.

According to FIG. 7 the robot 38 can load wafers onto two associated loading and unloading stations or remove wafers therefrom. It is also conceivable to bring the carrier 34 into a rotary position, such that only one of the stations 36 can be served by the robot 38. In the rotary position according to FIG. 7 the polishing units can then respectively remove one wafer from the loading and unloading station or deposit one wafer thereon. If, for example, the left polishing station 30 is for the first processing, in order to carry out subsequent processing in the right polishing station 31, the carrier 34 rotates about 180° after depositing a wafer on the associated loading and unloading station 36, so that the associated polishing unit 18 can remove the wafer again for its processing on the associated half of the polishing plate 20b. During the rotation of the carrier 34 the surface of the wafer can be cleaned, for example by means of the spray nozzle 74, in order to remove remainders of the processing medium and to avoid etching. Thus, the loading and unloading station 36 in conjunction with the carrier 34 is not only a means to centre received wafers, so that they can be received by the carrier 18 in a centred manner but also a transportation means between two or more polishing stations and a cleaning station for cleaning the processed wafers prior to further transport to the next polishing station or prior to removal by the robot 38.

The loading surfaces 54 can be of concave construction so that a chamber is formed on the rear face of the wafer 56, as already disclosed. They can be provided with bores in order to allow the drainage or supply of fluid. In this manner the rear face of the received wafer 56 can also be cleaned. The contact surface of the carrier can also be cleaned if it is lowered onto a loading surface.

It is understood that the disclosed drive means for individual parts of the polishing system and the cooperation of these drive means can be controlled by means of a suitable, not shown control device. Such control devices are generally known.

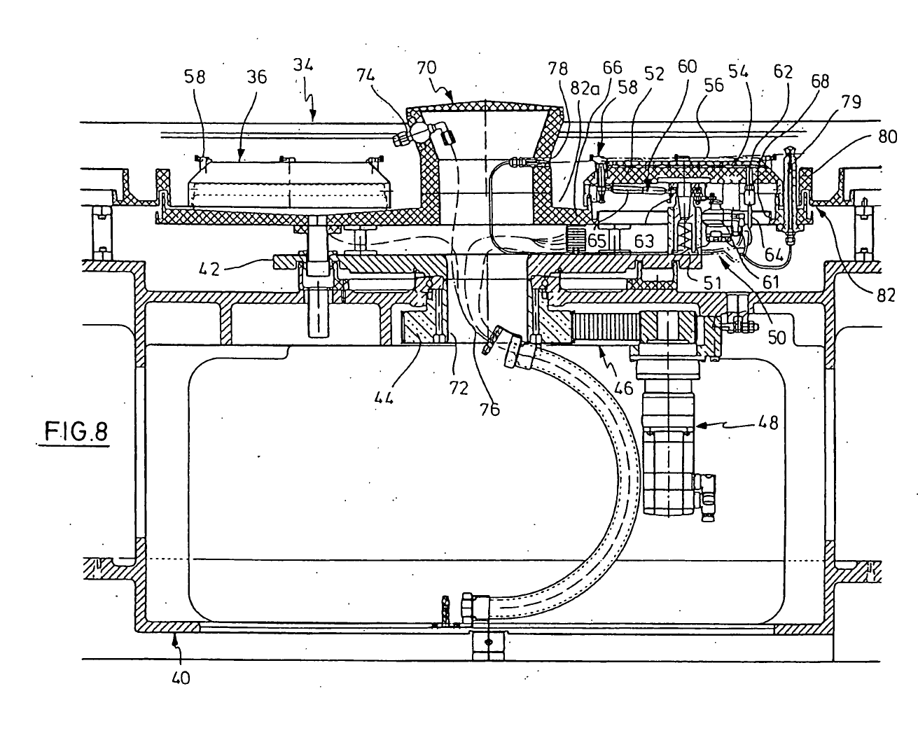

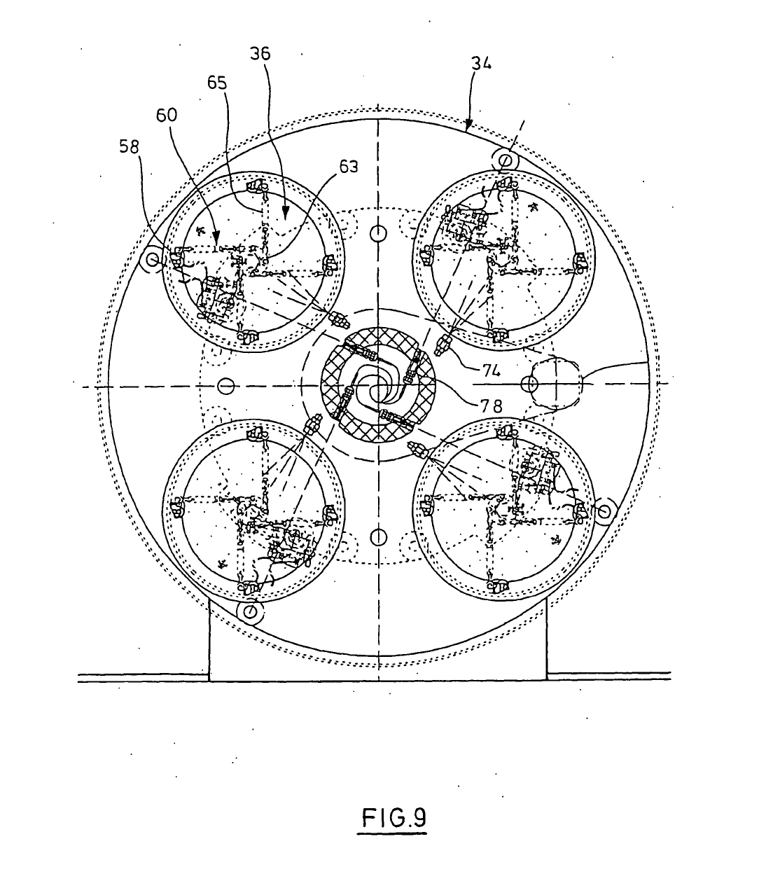

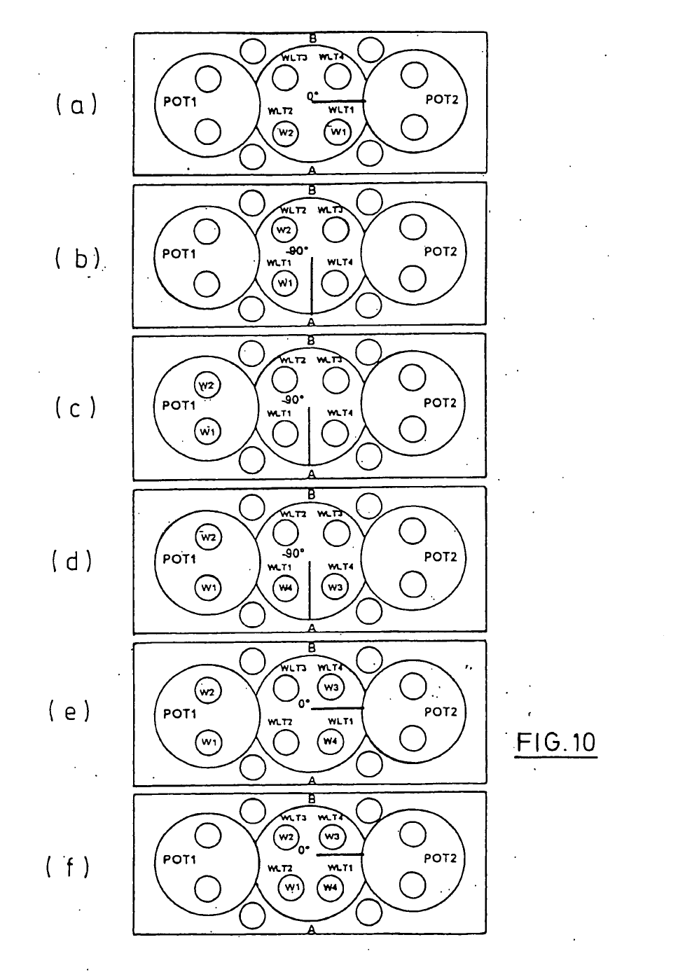

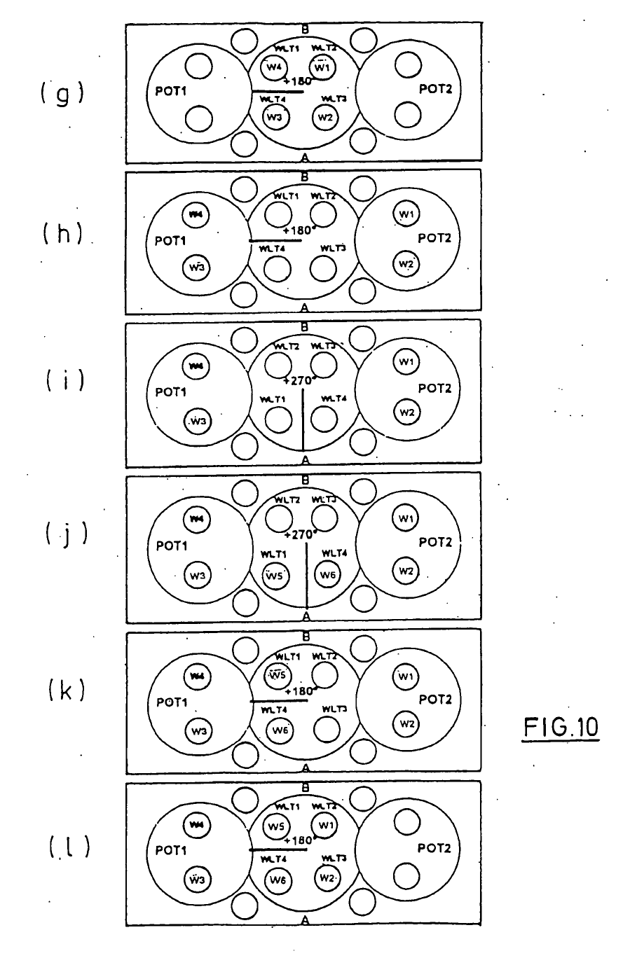

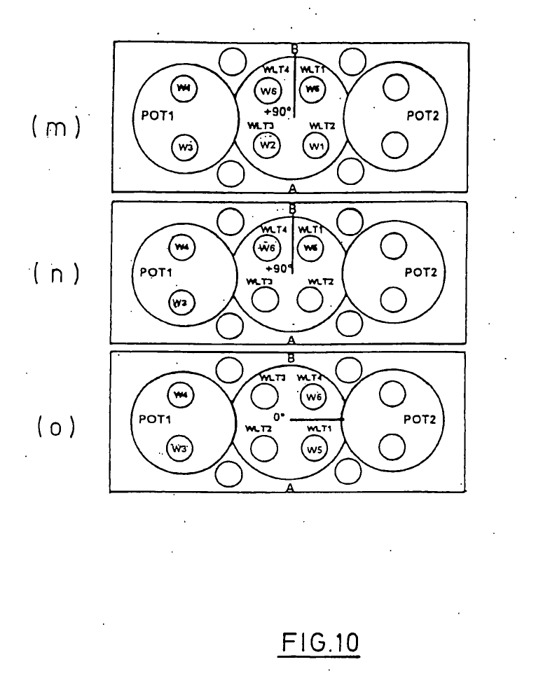

A two-step polishing method is to be described hereinafter with reference to FIG. 10a to FIG. 10o. A rotating carrier is arranged between two polishing plates POT1 and POT2 with the four loading surfaces WLT1 to WLT4. An arrangement can be used as is shown and disclosed in FIGS. 7 to 9. The transfer device 38 is not shown and also not the carrier (polishing units 18) by means of which the wafers can be transported and held against the polishing plates POT1 and POT2. In the case of FIG. 10 the transfer device is located on side A of the device. The diametrically opposing side is designated with B. For the sake of comprehension a radial line is shown in FIGS. 10a to 10o. In FIG. 10a it indicates a zero position of the carrier. In the remaining figures the position is indicated with 90° or a multitude of 90°.

In FIG. 10a the loading surfaces WLT1 and WLT2 are loaded with the workpieces W1 and W2. This takes place, as already mentioned, by means of the not shown transfer device, the loading able to take place simultaneously or also step-by-step. Subsequently the carrier is rotated about −90° according to FIG. 10b, whereby the workpieces W1 and W2 are facing the first polishing plate POT1. In this position the wafers can be picked up by the not shown carrier and moved above the polishing plate POT1. This can be seen in FIG. 10c. In the first polishing station the processing of the wafers W1 and W2 can now take place.

As soon as the wafers W1 and W2 are removed from the carrier, two further wafers W3 and W4 are deposited on the loading surfaces WLT1 and WLT4. As soon as this has taken place the carrier is rotated back about 90° into the zero position, as can be seen in FIG. 10e. In this position of the carrier the wafers W1 and W2 can be brought back to the loading surfaces WLT2 and WLT3 at the end of the polishing process. This is shown in FIG. 10f. Subsequently the carrier is rotated about 180° as can be seen in FIG. 10g. In this position the carriers which are associated with the polishing plate POT2 can transport the wafers W1 and W2 to the second polishing plate POT2 as is shown in FIG. 10h. The wafers W3 and W4 can simultaneously be moved from the associated carrier to the polishing plate POT1.

During the processing of the wafers W1 to W4 by the polishing plate POT1 and POT2 the loading surfaces WLT1 to WLT4 are empty. They can therefore be loaded with further wafers W5 and W6, as can be seen in FIG. 10j. According to FIG. 10k the carrier is then rotated in a clockwise direction, such that the wafers W5 and W6 are aligned with the polishing plate POT1, whilst the empty loading surfaces WLT2 and WLT3 are associated with the polishing plate POT2. In this position the completely processed wafers W1 and W2 can be placed on the associated loading surfaces, as can be seen in FIG. 101. Subsequently the carrier is rotated about a further 90°, so that the wafers W1 and W2 can be removed by the transfer device (FIGS. 10m and n). Thereafter the carrier is again rotated about 90°, so that the wafers W5 and W6 are aligned with the polishing table POT2, so that now the wafers W3 and W4 processed in the first step can be deposited on the carrier. Thereafter the further processing takes place as shown in FIG. 10f and thereafter.

Whilst the wafers W5 and W6 are on the loading surfaces, as already disclosed above, they can be pretreated, rinsed and cleaned. By these processes the entire throughput time is not extended in the two-step polishing of the wafers.

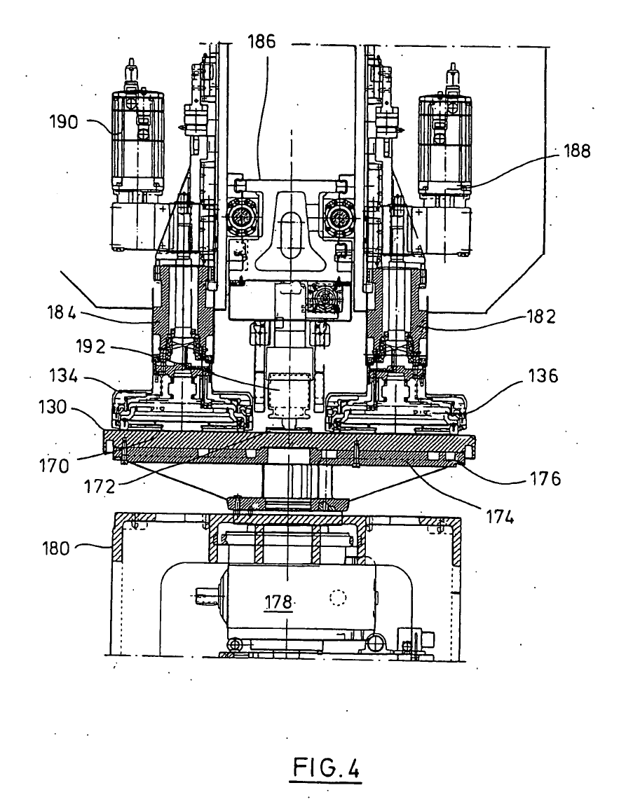

A polishing plate of the polishing device according to the above disclosed Figures is shown in section in FIG. 4. It is for example the polishing plate 130 according to FIG. 1. Accordingly, the polishing heads have the reference numerals 134, 136. A polishing cloth is stretched onto a work surface 170 and cooling ducts 176 are provided between a carrier plate 174 and the work plate 120, through which a suitable coolant flows. The supply and drainage of the coolant is not shown in detail.

The polishing plate 130 is driven by a drive means 178 which is arranged in a frame 180, via a vertical shaft. The polishing heads 134, 136 are connected to a spindle 182 and 184 which can be vertically adjusted in guide rails 186. The vertical adjusting drive is not shown. The drive means 188 and 190 can however be seen, with which the spindle 182, 184 can be displaced in rotation. At 192 a dressing mechanism is shown by means of which the polishing cloth can be dressed. It can be moved diametrically to the polishing plate 130, so that the entire surface of the polishing plate can be covered.

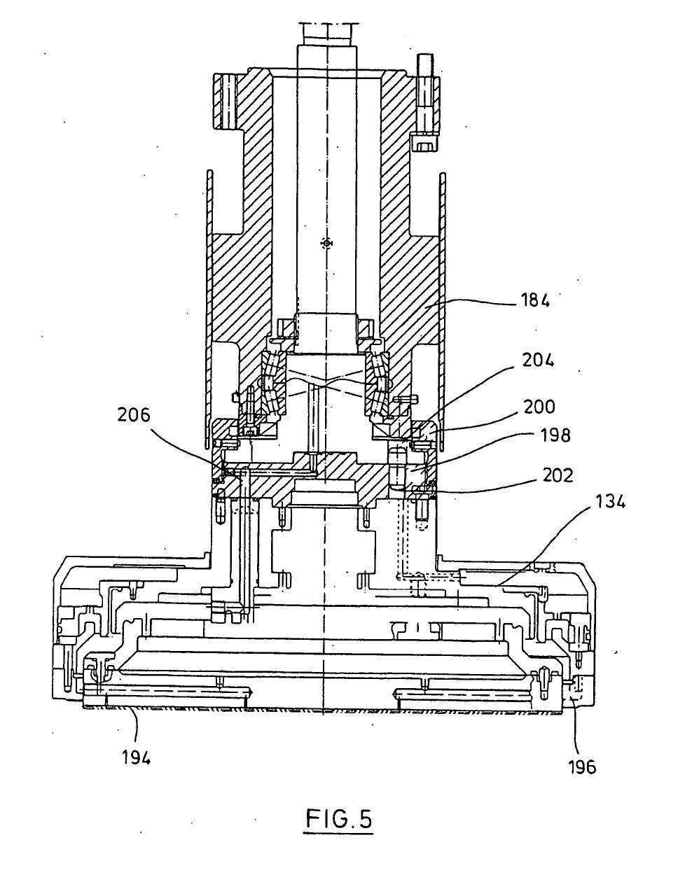

In FIG. 5 the polishing head 134 or carrier is shown enlarged. Further details of the polishing head are not to be described. A so-called backing film 194 can be seen via which the wafer is received by the polishing head 134. The slurry outlet is also seen at 196 which takes place out via an inlet in the spindle 184. This is not to be described in further detail. For the present description it is however important that an adapter plate 198 is connected to the polishing head 134, onto which a sleeve nut 200 can be screwed. The sleeve nut 200 can for its part be screwed onto an outer thread of the adapter plate 188. A centring pin 202 is connected to the adapter plate 198 which cooperates with a centring recess 204 of the spindle 184. In this manner a quick-release device is produced by means of which a polishing head can be rapidly attached to a spindle and released therefrom. The adapter plate 198 serves to ensure the supply of media to the polishing head 134, for example via the ducts indicated by 206.

It might also be mentioned with regard to the dressing device 192 according to FIG. 4, that it operates for example with diamond or plastics brushes or a high pressure water jet for the purpose of roughening the polishing cloth. The movement of these means takes place radially or diametrically, in order to achieve the desired roughening via the entire surface of the polishing cloth. Apart from the polishing plate 130, 132 (see also FIG. 1) means can also be provided to keep the dressing means wet.

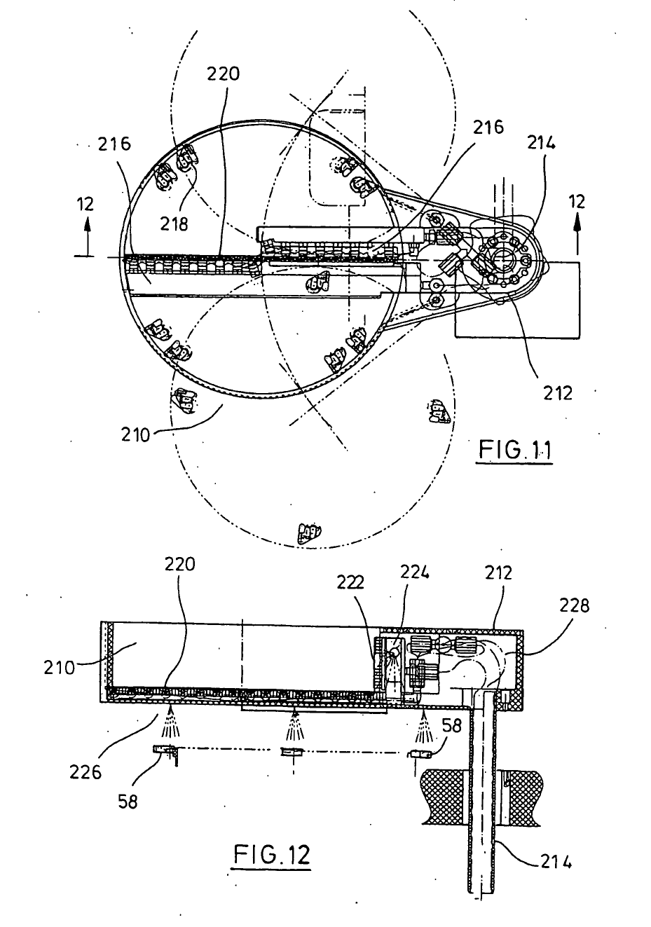

A circular tub 210 is shown in FIGS. 11 and 12. The tub 210 corresponds to one of the processing and cleaning stations 142 to 148 according to FIG. 1. A horizontal arm 212 is attached to the tub 210 to pivot the tub 210 about a vertical axis by means of a hollow shaft 214. The pivotability of the tub 210 is indicated in FIG. 11 by dotted lines.

In FIG. 11 horizontally arranged rows of spray and cleaning nozzles can be seen at 216 which are approximately radially arranged. In the tub pairs of centring means 218 can be seen at the edge, whose function is to be further described. In the tub a horizontal brush arrangement 220 is arranged. At one point of the edge of the tub 210 a horizontal brush arrangement 222 can be seen. Vertically arranged nozzles 224 are furthermore shown. Spray nozzles 226 are located in the base of the tub which downwardly release a medium. A plurality of media can be supplied through the hollow shaft 214 as is indicated by the ducts 228 as dotted lines in FIG. 12.

According to the preceding figures a polishing head can be lowered into the tub 210 with or without a received workpiece and at this point cleaned by means of brushes and cleaning nozzles. The centring means 218 centre the polishing head and allow it to rotate in the tub 210. If the tub 210 is arranged over a support surface 122 to 128 or over a carrier 34, according to FIG. 7 and thereafter, then the carrier, or the wafer received by the carrier, can also be cleaned. The medium can also be a treatment medium in order to treat the wafer in this manner.

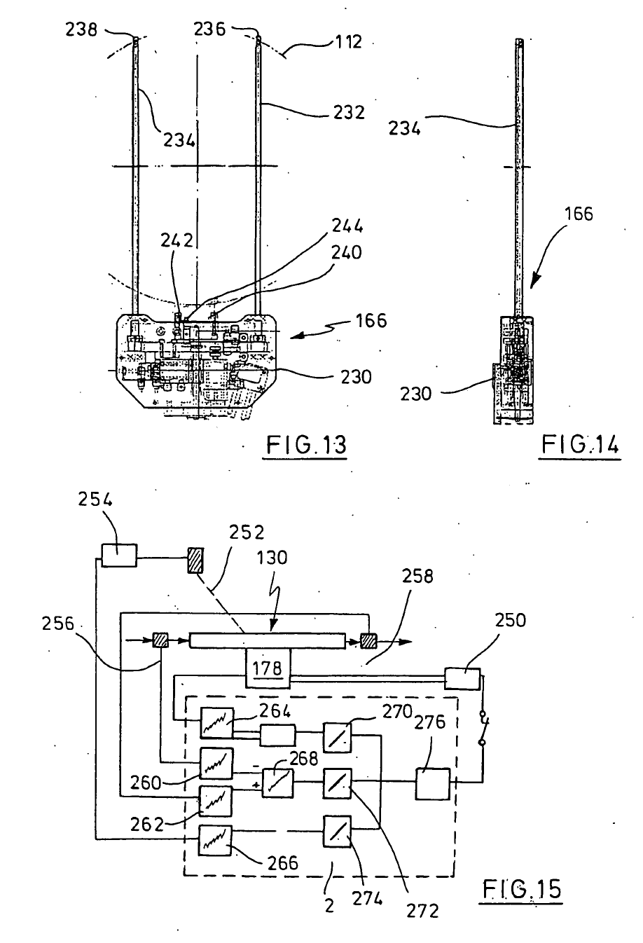

In FIGS. 13 and 14 the gripper of the robot 108 is shown in more detail. It is understood that the grippers of the robots 118 and 164 can be of similar construction. Two parallel shafts 232, 234 are rotatably mounted in a housing 230 and by means of a not shown drive means can be pivoted about 90°. The shafts 232, 234 are spaced apart from one another at specific intervals. The shafts 232, 234 comprise jaws 236, 238 at the ends made from abrasion resistant plastics, which are designed to pick up an edge of a wafer shown at 112. Pins 240, 242 are moreover linearly movably mounted in the housing 230 within the region of the shafts 232, 234. They are suitable for placing against the edge of a wafer 112. A wafer 122 can therefore be carefully picked up exclusively on the edge in the disclosed manner. It might again be emphasised that the mechanism for actuating the shafts and the pins of the gripper 166 is not to be described in detail. However the sensor 244 between the pins 242 and 240, with which the presence of a wafer 112 can be detected in the gripper 166, is still referred to.

In FIG. 15 the polishing plate 130 is for example diagrammatically indicated. The motor 178 is actuated by a control device 250. A sensor 252 is associated with the polishing plate 130 which measures the temperature on the surface of the polishing plate and transmits it to a transducer 254. A sensor 256 measures the temperature of the cooling medium which, as disclosed, is sent through the polishing plate 130. A sensor 258 measures the output temperature of the coolant. Both temperature values are transmitted to transducers 260 and 262 in which these values are stored. The power consumption of the drive motor 178 is stored in the transducer. The surface temperature is stored at 266. From the input and output temperature of the coolant of the polishing plate 130 a difference is formed and stored at 268. The temperature variation is detected by suitable filters 270, 272 and 274 and the temperature variations of the disclosed parameters are used at 276 by means of a suitable algorithm to form a cut-out signal for the control device 250. It can be determined by means of the disclosed data and the algorithm when a layer transition takes place on the wafer. This indicates the end of a polishing process, so that the polishing device can be automatically switched off. The operating methods of the individually disclosed devices will once again be described hereinafter.

A processing cycle begins, after at least one platform 104 is loaded with a cassette 106. In the first step, identification and processing data are read from the data carrier of the cassette 106 by means of the identification device. The read data are used further in the course of the processing step in order to associate the accumulating process data clearly with a cassette. In the next step verification of the cassette loading takes placed via the already disclosed mapping device which checks the loading and orientation of the workpieces 112 in the cassette 106. After the verification the robot 108 removes the wafers 112 from the storage racks of the cassettes 106 and transports them to the recognition system 110 and then to the transfer point 116. During transportation the wafers are only picked up by the edge region in order to avoid scratches on the surface and contamination. The second robot 118 removes the wafer from the transfer point 114, at which the layer thickness is measured and transports it to one of the support surfaces 122, to 128 of the carrier or the intermediate station 120. This transportation also takes place by picking up the edge of the wafer with the gripping means of the robot 118. After the robot 118 has deposited the wafer, for its part it can undergo cleaning in a not shown cleaning station, before it picks up the next wafer, for example in order to transport the wafer processed by the polishing plate 132 from a support surface of the intermediate station 120 to the cleaning and washing device 154, 156. The polishing and treatment in the polishing device and in the intermediate station 120 is not to be described further as it has already been extensively described above.

Before the polishing heads place a wafer on the intermediate station 120, the polishing heads can be lowered in the cleaning and processing stations 142, 144, 146, 148 and cleaned or treated there. Only then are the wafers deposited in the intermediate station 120. It is however necessary for the associated tub 210 to be first pivoted into a parking position, so that the polishing head can be lowered onto a support surface of the intermediate station 120. It is however also possible to deposit a wafer first and then to carry out cleaning of the polishing head in the tub 210 of the cleaning and processing station. For this it is also necessary that it is pivoted from the parking position shown in FIG. 1 into a position in which it is aligned with a support surface.

After lowering the wafers onto the polishing plate 130, 132 the polishing process takes place, it being completed when the measured parameters for the temperatures and power consumption of the drive motor for the polishing plate indicate that a layer transition is taking place.

The robot 118 removes the completely processed workpiece or the completely polished wafer from the intermediate station 120 and places it in the input area 158 of the washing and drying station. Subsequently the washing and drying of the wafers takes place and at the output region of the drying device 162 (centrifugal rinsing and drying device) the robot 164 removes the cleaned and dried wafer out of the drying device 162 and deposits it in the transfer point 114, where its thickness is checked by means of the already disclosed thickness gauge 116. Subsequently, it is transported back into a cassette 106 by means of the robot 108.

Different filter and ventilation units are associated with the clean room 100, so that different clean room areas are created. In the region of the robot 108 a class 1 clean room is created. Filter and ventilation units which are arranged over the cleaning and drying device, create a class 2 clean room. The second robot 118 and the thickness gauge 116 operate in a class 3 clean room. The entire polishing device including the intermediate station operates in a class 4 clean room. The ventilation units which are attached to the ceiling of the clean room 100, create a laminar airflow of which the flow speed can be steplessly varied. By varying the air flow speeds in the individual areas, different pressure zones are created which allow the air flow to be geometrically guided. The filters are equipped so that they can produce the respectively required clean room class.

The above disclosure is intended to be illustrative and not exhaustive. This description will suggest many variations and alternatives to one of ordinary skill in this art. All these alternatives and variations are intended to be included within the scope of the claims where the term “comprising” means “including, but not limited to”. Those familiar with the art may recognize other equivalents to the specific embodiments described herein which equivalents are also intended to be encompassed by the claims.

Further, the particular features presented in the dependent claims can be combined with each other in other manners within the scope of the invention such that the invention should be recognized as also specifically directed to other embodiments having any other possible combination of the features of the dependent claims. For instance, for purposes of claim publication, any dependent claim which follows should be taken as alternatively written in a multiple dependent form from all prior claims which possess all antecedents referenced in such dependent claim if such multiple dependent format is an accepted format within the jurisdiction (e.g. each claim depending directly from claim 1 should be alternatively taken as depending from all previous claims). In jurisdictions where multiple dependent claim formats are restricted, the following dependent claims should each be also taken as alternatively written in each singly dependent claim format which creates a dependency from a prior antecedent-possessing claim other than the specific claim listed in such dependent claim below.

This completes the description of the preferred and alternate embodiments of the invention. Those skilled in the art may recognize other equivalents to the specific embodiment described herein which equivalents are intended to be encompassed by the claims attached hereto.

1. Method for transporting, chemical-mechanical polishing and drying of workpieces, in particular silicon wafers in a sealed clean room with the following steps:
the workpieces are removed by at least one transfer device from a loading and unloading station and transferred onto an intermediate station
the workpieces are received by at least one polishing head of a polishing device of the intermediate station, transported to a polishing plate of the polishing device and held under rotation of the polishing head against the rotating polishing plate
after polishing, the workpieces are transported back by the polishing head to the intermediate station, released from the polishing head and cleaned and/or chemically treated in the intermediate station
the cleaned and/or chemically treated workpieces are transported from the intermediate station optionally to a second polishing device or to a washing or drying device and washed and dried therein
the washed and dried workpieces are transported back by the transfer device to the loading and unloading station
the polishing head is cleaned before each workpiece is received.

2. Method according to claim 1, characterised in that the workpieces are removed with a first transfer device from a loading and unloading station and placed on a first transfer point, the workpieces being transported by a second transfer device from the transfer point to the intermediate station.

3. Method according to claim 2, characterised in that the cleaned and dried workpieces are transported back by the first transfer device to the loading and unloading station.

4. Method according to claim 1, characterised in that the workpieces processed by the first polishing device are transported by means of a second polishing head from the intermediate station to a second polishing device and held against a second polishing plate of the second polishing device and after polishing transported back to the intermediate station.

5. Method according to claim 1, characterised in that gripper means of the transfer device or the first and second transfer device are cleaned before each workpiece is picked up.

6. Method according to claim 1, characterised in that the workpieces are chemically treated in the intermediate station.

7. Method according to claim 1, characterised in that the gripper means of the transfer device or the first and second transfer device pick up the workpieces only at their edge.

8. Method according to claim 1, characterised in that from the temperature variation measured on the surface of the polishing plate and the variation of the load of a drive means for driving the polishing plate a signal is derived for switching off the drive means.

9. Method according to claim 8, characterised in that the polishing plate is cooled by a liquid and the temperature variation of the difference between the inflow and the outflow of the liquid is taken into consideration when the shutoff signal is derived.

10. Method according to claim 1, characterised in that the workpieces in the intermediate station are moved from a point for depositing and receiving the polishing head and during the movement are cleaned and/or chemically treated.

11. Device for the chemical-mechanical polishing of the surface of circular, flat workpieces, in particular semiconductor wafers, with
an intermediate station for the workpieces, to which the workpieces to be processed are transported by a transfer device and into which processed workpieces are deposited, before they are unloaded after a cleaning and drying process, the intermediate station comprising:
a carrier (34) rotatably mounted about a vertical axis which can be brought into a predetermined position by a rotary drive (48) and at least two horizontal, upwardly exposed loading surfaces (54) on the carrier (34), furthermore with
a transfer device (38) with which workpieces can be placed on the loading surface (54) or removed therefrom
at least two polishing plates (20a, 20b) comprising polishing stations (30, 31) which are arranged on the circumference of the carrier (34),
at least one polishing head (18) for the workpieces (56) for each polishing station, which is moved by means of an adjusting device along a vertical and a horizontal axis to be vertically aligned with a loading surface (54), for receiving and depositing a workpiece (56) and for transporting the workpieces (56) to the associated polishing station (30, 31) and therefrom, in addition to cooperating with the polishing plate (20a, 20b) of the associated polishing station (30, 31) and
a control device for the rotary drive device and the adjusting device.

12. Device according to claim 11, characterised in that a centring device (58, 60) is provided on the carrier (34) for each loading surface (54) which grip onto the circumference of a workpiece (56) on the loading surface (54) with centring means which are actuated by an actuation device, in order to align the workpiece (56) radially to a predetermined vertical axis.

13. Device according to claim 11, characterised in that a device (74) associated with the carrier (34) for cleaning and/or hydrophilising and/or keeping the upper surface of the workpieces (56) wet on the loading surfaces (54) is provided.

14. Device according to claim 11, characterised in that four loading surfaces (54) are provided on the carrier (34).

15. Device according to claim 11, characterised in that four loading surfaces (54) are provided on the carrier, that linear guides (10a, 10b) are associated with each polishing station (30,31) for two independently guided carriers (18) and the loading surfaces (54) are arranged such that in a predetermined rotary position of the carrier (34) the vertical axis of a loading surface (54) and the carrier (18) lie in a common vertical plane which extends parallel to the guides (10a, 10b).

16. Device according to claim 11, characterised in that the carrier (34) comprises a central elevation (70) in which nozzles (74) aligned to the loading surfaces (54) are arranged, which are connected to a fluid source.

17. Device according to claim 16, characterised in that detectors (78) are arranged in the elevation (70) which determine whether a workpiece (56) is arranged on the loading surfaces (54).

18. Device according to claim 11, characterised in that the carrier (34) is encircled by the side wall (80) of a dripping tub for the entire system which extends below the carrier (34).

19. Device according to claim 18, characterised in that a dripping tub (82a) is associated with each loading surface (54) and which comprises an outlet to the dripping tub for the entire system.

20. Device according to claim 11, characterised in that the centring means for each loading surface comprise a plurality of axial movable centring cams (58) arranged spaced apart on a circle with support surfaces for the edge regions of a workpiece (56) and with stop surfaces which can be brought into engagement with the circumference of a workpiece (56) when the centring cams (58) are radially adjusted, an actuation device (60) synchronously radially adjusting stop surfaces in order to align the axis of the workpiece (56) to the predetermined vertical axis.

21. Device according to claim 11, characterised in that the loading surfaces (54) are concave and comprise bores for the drainage of liquid which collects on the loading surface (54) and/or nozzles for cleaning the rear face of a workpiece (56) on the loading surface (54).

22. Device according to claim 11, characterised in that the loading surfaces (56) are constructed on the upper face of a separate cap-shaped element (52) which is supported by a trunnion-shaped upright support portion (50) of the carrier (34).

23. Method for the chemical-mechanical polishing of the surface of semiconductor wafers by means of two polishing stations, each comprising a polishing plate, two carriers for each polishing station which independently from one another are moved vertically and horizontally, four loading surfaces of which the centre lies on a circle and which can be rotated together about a vertical axis and which are arranged between the polishing stations such that in defined common rotary positions, which are spaced about an angle of 90° or a multitude of 90°, two loading surfaces are respectively aligned with the linear transport path of two carriers belonging to a polishing station and in a predetermined rotary position and by means of a loading and unloading device, with which in a predetermined rotary position of the loading surfaces two loading surfaces can be respectively loaded with a workpiece or have a workpiece removed, with the following method steps:
a) after loading two loading surfaces with a first and a second workpiece the loading surfaces are rotated about 90°, whereby the workpieces are aligned with the first polishing station and are moved by the carriers of the first polishing station to the polishing plates to carry out a first polishing process
b) after removing the first and second workpiece by the carrier a third and fourth workpiece are deposited on the associated loading surfaces and by rotating the loading surfaces about 90° are aligned with the second polishing station, whereafter the first and second workpiece are removed by the carriers from the first polishing station and deposited on the facing free loading surfaces
c) after rotating the loading surfaces about 180° the first and second workpiece are transported by the carriers of the second polishing station and the third and fourth workpiece are transported by the carriers of the first polishing station to the appropriate polishing plate
d) after finishing the polishing process the workpieces are deposited on associated loading surfaces and the third and fourth workpiece aligned to the second polishing station and the first and second workpiece removed from the loading and unloading device, so that subsequently a loading with a fifth and sixth workpiece can take place.

24. Method according to claim 23, characterised in that after step c) a fifth and sixth workpiece are deposited on the associated loading surfaces and after rotating about 90° aligned with the second polishing station and are deposited on the facing loading surfaces and after rotating of the loading surfaces about 90° the first and second workpiece are removed and by rotating about a further 90° the free loading surfaces are aligned with the first polishing station to receive the third and fourth workpiece and for the subsequent transportation to the second polishing station and for the transportation of the fifth and sixth workpiece to the first polishing station.

25. Device for transporting, chemical-mechanical polishing and cleaning and drying of workpieces, in particular silicon wafers in a sealed clean room with the following features
a loading and unloading station (102) for the workpieces
at least one transfer device with gripping means for the transportation of the workpieces (112) from the loading and unloading station to an intermediate station (120)
a polishing device with at least one polishing plate (130, 132) and at least one polishing head (134, 136, 138, 140), the polishing head comprising means for holding a workpiece (112) and can be adjusted in its height and horizontally between the intermediate station (120) and the polishing plate (134 to 140)
means for cleaning and/or chemical treatment of the polishing head and/or the workpiece in the intermediate station (120)
and a washing and drying device (154, 156, 162) for the processed workpieces.

26. Device according to claim 11, characterised in that a processing and cleaning station (142 to 148) is associated with the intermediate station (120), and into which the workpieces (112) together with the polishing head can be brought or into which the polishing head can be brought for processing and cleaning purposes.

27. Device according to claim 26, characterised in that the processing and cleaning station (142 to 148) is arranged over the intermediate station (120) and the carrier (34).

28. Device according to claim 26, characterised in that the processing and cleaning station (142 to 148) comprises a tub (210) which is provided with cleaning nozzles.

29. Device according to claim 28, characterised in that the processing and cleaning station (144 to 148) comprises downwardly directed cleaning nozzles (226).

30. Device according to claim 26, characterised in that the processing and cleaning station (144 to 148) comprises cleaning brushes (220) to clean the received workpiece or the polishing head.

31. Device according to claim 25 characterised in that the polishing head (134) can be exchangably attached to a spindle (184).

32. Device according to claim 25, characterised in that the gripping means for flat, circular workpieces (112) comprise two parallel spaced rigid shafts (234, 232) rotatably mounted in a gripper housing (230) which comprise gripping jaws (238, 236) on the end which can be brought into engagement in a rotary position with an edge of a workpiece (112).

33. Device according to claim 22, characterised in that between the shafts (232, 234) in the vicinity of the housing (230) gripping jaws (240, 242) are arranged which can be moved laterally.

34. Device according to claim 25, characterised in that the gripping means (166) comprise a sensor (244) which detects the receipt of a workpiece (112).

35. Device according to claim 25, characterised in that a dressing device (192) is provided for the polishing plate (130) which comprises a dressing unit which can be moved diametrically over the polishing plate (130).

36. Device according to claim 35, characterised in that the dressing component produces a high pressure jet.

37. Device according to claim 36, characterised in that the dressing component comprises a rotary driven dressing brush.

38. Device according to claim 37, characterised in that a tank is provided for keeping the dressing brushes wet, in which the dressing brushes are held cleaned and damp.
